(19) United States
(12) Patent Application Publication
(10) Pub. No.: US 2026/0068215 A1
(43) Pub. Date: Mar. 5, 2026

(54) GUARD RING AND SUPPLY FOR HIGH-CURRENT SWITCH-MODE VOLTAGE CONVERTERS

(71) Applicant: TEXAS INSTRUMENTS INCORPORATED, Dallas, TX (US)

(72) Inventors: Thomas Keller, Attenkirchen (DE); Michael Sulecki von, Freising (DE); Markus Rommel, Freising (DE)

(21) Appl. No.: 18/820,927

(22) Filed: Aug. 30, 2024

(51) Int. Cl. H01L 29/78; H01L 27/088; H01L 29/06

(52) U.S. Cl. CPC H10D 30/655; H10D 62/107; H10D 84/83

(57) ABSTRACT

Some aspects relate to a device comprising a power circuit, a control circuit, a guard ring, a guard wall, and a voltage generator. The power circuit is disposed within a substrate and includes a transistor of a first type. The control circuit is disposed within the substrate and includes a transistor of a second type different from the first type, and is coupled to the power circuit. The guard ring includes a plurality of doped regions within the substrate, and the guard ring laterally surrounds the power circuit. The guard wall is disposed within the substrate and between the guard ring and the control circuit. The guard wall includes a first doped region laterally surrounding an insulating region, and a polysilicon region laterally surrounded by the insulating region. The voltage generator has a first terminal coupled to the first doped region of the guard wall.

### BACKGROUND

An arrangement of transistors can be used in a switch-mode voltage converter which is used to convert a voltage to either a larger or a smaller value. A control circuit is used to control the switch-mode voltage converter.

### SUMMARY

Some aspects relate to a device comprising a power circuit, a control circuit, a guard ring, a guard wall, and a voltage generator. The power circuit is disposed within a substrate and includes a transistor of a first type, and the power circuit has a ground terminal coupled to a first ground supply terminal. The control circuit is disposed within the substrate and includes a transistor of a second type different from the first type. The control circuit is coupled to the power circuit, and the control circuit has a ground terminal coupled to a second ground supply terminal different from the first ground supply terminal. The guard ring includes a plurality of doped regions within the substrate, and the guard ring laterally surrounds the power circuit. The guard wall is disposed within the substrate and between the guard ring and the control circuit. The guard wall includes a first doped region laterally surrounding an insulating region, and a polysilicon region laterally surrounded by the insulating region. The polysilicon region of the guard wall is connected to the second ground supply terminal. The voltage generator is within the substrate, and the voltage generator has a first terminal coupled to the first doped region of the guard wall.

Some aspects further relate to an integrated circuit comprising a first transistor, a second transistor, a circuit, and a guard ring. The first transistor has a first terminal, a second terminal, and a control terminal. The second transistor has a first terminal, a second terminal, and a control terminal. The first terminal of the second transistor is connected to the second terminal of the first transistor. The circuit has an input terminal, a first output terminal, and a second output terminal. The input terminal is coupled to the second terminal of the first transistor. The first output terminal is coupled to the control terminal of the first transistor, and the second output terminal is coupled to the control terminal of the second transistor. The first transistor, the second transistor, and the circuit are all implemented on a substrate. The guard ring includes a first doped region, a second doped region, a third doped region, and a buried doped region. The buried doped region laterally surrounds the first transistor and the second transistor. The second doped region extends further into the substrate than the first doped region or the third doped region. The second doped region contacts the buried doped region.

Some further aspects relate to an integrated circuit comprising a first circuit, a second circuit, a first doped region, a second doped region, a third doped region, and a polysilicon region. The first circuit is disposed within a substrate. The second circuit is disposed within the substrate, and spaced apart from the first circuit. The first doped region laterally surrounds the first circuit when viewed from a top-down view, and the first doped region has a first doping polarity. The second doped region laterally surrounds the first doped region when viewed from the top-down view, and the second doped region has a second doping polarity. The second doping polarity is opposite the first doping polarity. The third doped region laterally surrounds the second doped region when viewed from the top-down view, and the third doped region has the first doping polarity. The second doped region extends further into the substrate than both the first doped region and the third doped region when viewed in a cross-sectional view. The polysilicon region extends along a linear segment that separates the first circuit and the second circuit when viewed from the top-down view. The polysilicon region does not entirely laterally surround the first circuit when viewed from the top-down view, and does not entirely laterally surround the second circuit when viewed from the top-down view.

### BRIEF DESCRIPTION OF THE DRAWINGS

FIG. 1 shows an example of circuit schematic of a switch-mode voltage converter.

FIG. 2 shows a top/layout view of components of the switch-mode voltage converter implemented on a substrate.

FIG. 3 shows a series of timing diagrams that illustrate noise on ground terminals of a switch-mode voltage converter.

FIG. 4A shows an example of a more detailed layout of a switch-mode voltage converter implemented on a substrate.

FIG. 4B-1 shows a cross-section from FIG. 4A.

FIG. 4B-2 shows another cross section from FIG. 4A.

FIG. 5A shows another example of a more detailed layout of a switch-mode voltage converter implemented on a substrate.

FIG. 5B-1 shows a cross-section from FIG. 5A.

FIG. 5B-2 shows another cross-section from FIG. 5A.

FIG. 5C shows another example of a more detailed layout of a switch-mode voltage converter implemented on a substrate.

FIG. 6 shows an example power metal oxide field effect transistor (MOSFET) cross-section consistent with some examples of FIGS. 4-5.

FIG. 7 shows an example of a planar MOSFET cross-section consistent with some examples of FIG. 4.

FIG. 8 shows a cross-section of a guard ring.

FIG. 9 shows a top/layer view that includes an alternative embodiment of a guard wall in a C-shape.

FIG. 10 shows a top/layer view that includes an alternative embodiment of a guard wall surrounding a control circuit.

FIG. 11 shows a top/layer view that includes an alternative embodiment of a guard wall surrounding a guard ring.

FIG. 12 shows a top/layer view that includes an embodiment of the guard wall implemented in a switch-mode voltage converter that has a stair-stepped pattern.

FIG. 13-1 shows an example cross-section of FIG. 12 of a thin region of guard ring.

FIG. 13-2 shows an example cross-section of FIG. 12 of a thick region of a guard ring.

FIG. 14-1 shows another example cross-section of FIG. 12 of a thin region of a guard ring

FIG. 14-2 shows another example cross-section of FIG. 12 of a thick region of a guard ring.

### DETAILED DESCRIPTION

A switched-mode converter has a power circuit and a control circuit in or on a semiconductor substrate. The power circuit has transistors capable of switching high voltages/high currents in order to convert an input voltage to an output voltage. The control circuit contains a noise sensitive circuit used in a feedback loop to control the transistors in the power circuit. Due to the transistors of the switched-mode converter switching high voltages and/or currents, a significant amount of noise can be generated by the power circuit and injected into the substrate. This noise can interfere with the noise sensitive circuit in the control circuit. Thus, the present disclosure includes a guard ring and a guard wall. The guard ring and guard wall minimize noise by collecting minority carriers (electrons) in the substrate and by supporting recombination of minority electrons with holes. The guard ring, which is coupled to the substrate, laterally surrounds the power circuit to limit most of the carriers that are generated by the power circuit from causing undesired leakage that can adversely affect other areas of the circuit. The guard wall is placed between an outer edge of the guard ring and the control circuit to further reduce any remaining stray carriers generated by the power circuit. Thus, the guard wall that is connected to a positive potential with respect to the substrate collects the remaining stray carriers before they reach the noise sensitive circuit to minimize the impact of the noise on the noise sensitive circuit. In many cases, the guard wall is a line or series of lines that do not completely laterally enclose the noise sensitive circuit when viewed from above, which limits the footprint of the guard wall on the substrate and thereby provides good protection for the noise sensitive circuit while also limiting cost/area.

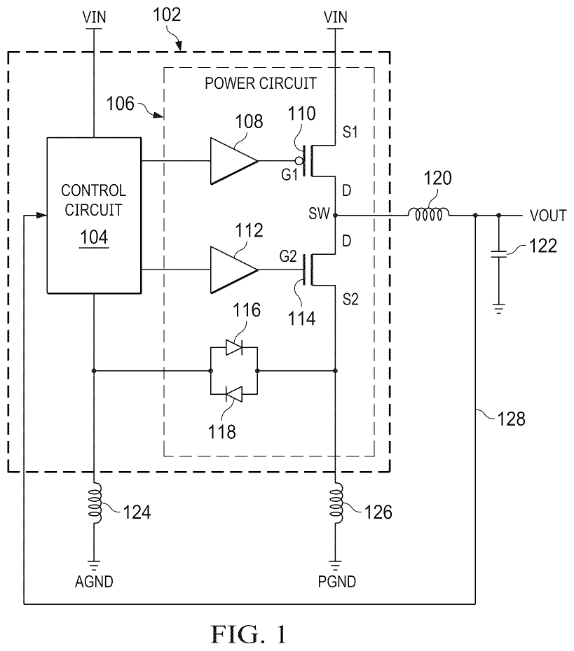

FIG. 1 shows a switch-mode voltage converter including a switch-mode voltage converter chip 102. The switch-mode voltage converter chip 102 includes a control circuit 104 and a power circuit 106. The power circuit 106 has a first gate driver 108 and a second gate driver 112. The power circuit 106 further has a first transistor 110 and a second transistor 114. The power circuit 106 further has a first diode 116 and a second diode 118. The first transistor 110 and the second transistor 114 each have a first terminal, a second terminal, and a control terminal. The switch-mode voltage converter also includes a first inductor 120, a capacitor 122, a second inductor 124, and a third inductor 126. FIG. 1 further shows a voltage supply terminal (VIN), an output voltage terminal (VOUT), an analog ground supply terminal (AGND), and a power ground supply terminal (PGND).

The switch-mode voltage converter chip 102 is coupled to VIN, the first inductor 120, the second inductor 124, and the third inductor 126. The first inductor 120 is coupled to the capacitor 122. The second inductor 124 is coupled to AGND. The third inductor 126 is coupled to PGND. The control circuit 104 has a voltage input terminal connected to VIN.

The first gate driver 108 has an input coupled to a first output of the control circuit 104 and has an output coupled to a gate of the first transistor 110. The second gate driver 112 has an input coupled to a second output of the control circuit 104 and has an output coupled to a gate of the second transistor 114. The first transistor 110 has a source terminal coupled to VIN, and has a drain terminal coupled to an internal node and pin labeled SW. The SW node is coupled to a drain terminal of the second transistor 114 and to a first terminal of the first inductor 120. The first diode 116 has a cathode connected to an anode of the second diode 118 and an anode connected to the cathode of second diode 118. The cathode of the first diode 116 is also coupled to a source terminal of the second transistor 114, and to a first terminal of the third inductor 126. The second diode 118 has a cathode connected to the control circuit 104 and to a first terminal of the second inductor 124. The first inductor 120 has a second terminal coupled to VOUT. The capacitor 122 is coupled between VOUT and a ground. The second inductor 124 has a second terminal coupled to AGND. The third inductor 126 has a second terminal coupled to PGND. The control circuit 104 is connected to VOUT through a feedback loop 128. The control circuit 104 is coupled to VIN. The first transistor 110 and the second transistor 114 may be metal oxide field effect transistors (MOSFETs).

The control circuit 104 controls the first gate driver 108 and the second gate driver 112 to turn the first transistor 110 and the second transistor 114 into either a conductive, or ON, state or a non-conductive, or OFF, state. The controls to the first gate driver 108 and the second gate driver 112 are responsive to the feedback loop 128 from VOUT. The switching of the first transistor 110 and the second transistor 114 causes noise to develop within the circuit. This noise can impact various parts of the control circuit 104.

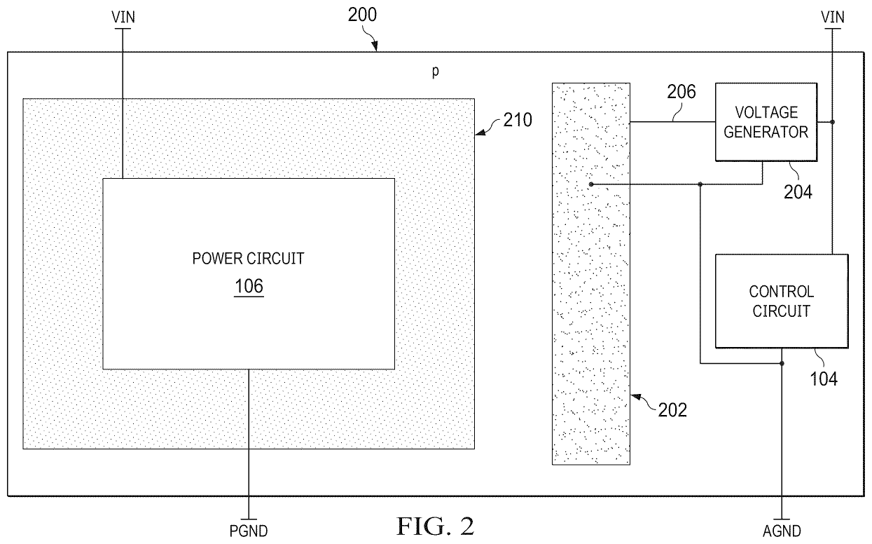

FIG. 2 shows a top/layout view of a substrate 200 that includes a switch-mode voltage converter chip 102, such as previously shown in FIG. 1. Thus, the switch-mode voltage converter chip 102 includes the control circuit 104 and power circuit 106. The switch-mode voltage converter chip 102 also includes a guard ring 210, a guard wall 202, and a voltage generator 204.

The guard ring 210 laterally surrounds the power circuit 106. The control circuit 104 is outside of the guard ring 210, and the control circuit 104 is spaced from the power circuit 106. The guard wall 202 is located between the guard ring 210 and the control circuit 104 and voltage generator 204. The voltage generator 204 is located near the control circuit 104, and the voltage generator 204 has a connection 206 to the guard wall 202. The voltage generator 204, control circuit 104, and the guard wall 202 all have ground terminals connected to AGND which is also substrate potential. The voltage generator 204 and the control circuit 104 are connected to VIN and each of them might contain voltage generator(s) to provide stabilized voltages.

Because the transistors of the power circuit 106 can switch high voltages and/or currents when in operation, the power circuit 106 can cause minority carriers to be injected into the substrate 200. This noise that is generated by the power circuit 106 is reduced by both the guard ring 210 and the guard wall 202.

The guard ring 210 reduces the noise by both collecting the minority charge carriers that passed the guard ring 210, and by supporting recombination of the minority charge carriers with holes. Furthermore, the guard wall 202 is biased by the voltage generator 204 through connection 206 to attract the minority charge carriers to be collected and removed from the substrate. The voltage generator 204 might have noise on its output voltage depending on the number of carriers collected and is used as supply for the guard wall 202 to avoid coupling noise through the supply rail into noise sensitive circuits. Thus, overall the minority carriers and the noise from the minority carriers is reduced.

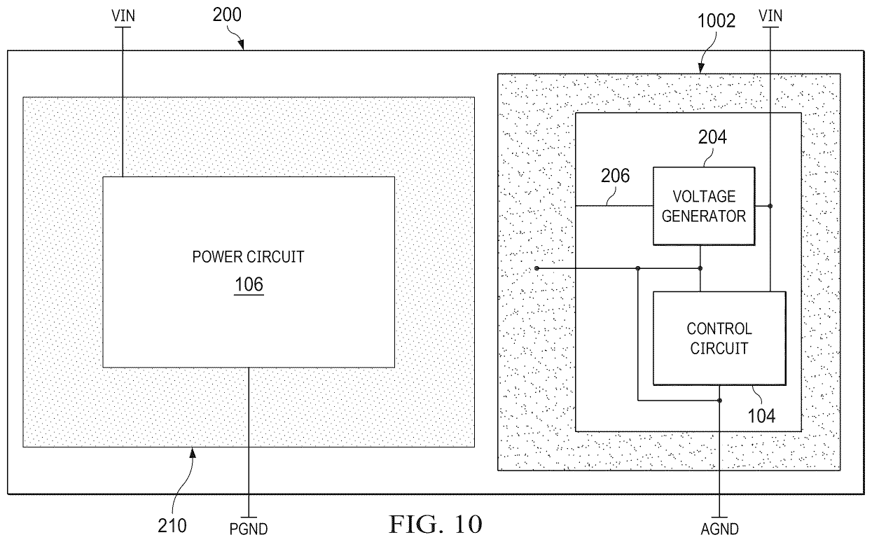

In the illustrated example of FIG. 2, the guard wall 202 is a single line when viewed from above that is arranged between an outer edge of the guard ring 210 and the control circuit 104 and voltage generator 204. Thus, the guard wall 202 separates the power circuit 106 and control circuit 104, but does not completely laterally enclose the control circuit 104 together with voltage generator 204 when viewed from above. In other cases, the guard wall 202 could be replaced by a second guard ring that completely laterally encloses the control circuit when viewed from above (see e.g., FIG. 10). However, compared to a second guard ring, the guard wall 202 that consists of a single line as shown in FIG. 2 limits the footprint/area of the guard wall 202 and thereby provides sufficient protection for the noise sensitive circuit while also limiting cost/area.

In some examples, the substrate 200 is a monocrystalline silicon substrate, or is a silicon on insulator (SOI) substrate. In some examples, the substrate 200 is a p-type substrate, but in other examples the substrate 200 may be an n-type substrate. The minority carriers for an n-type substrate are holes, and the minority carriers in a p-type substrate are electrons.

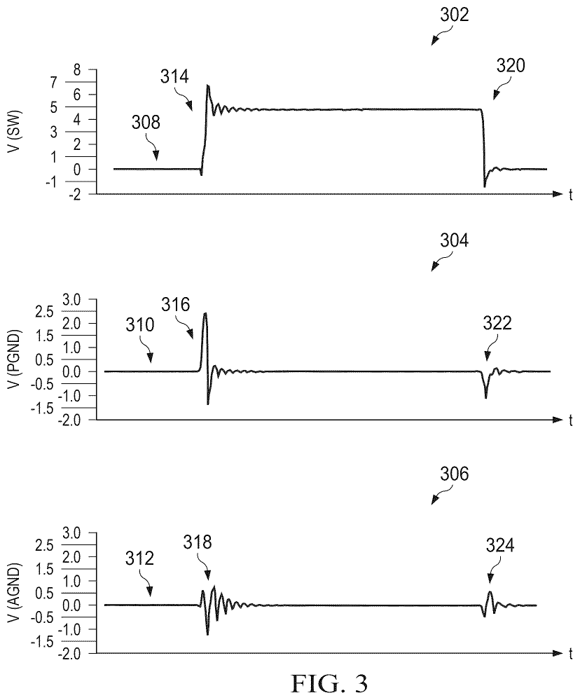

FIG. 3 shows waveforms of signals at the SW node, PGND, and AGND when the control circuit 104 causes a switch to occur. Graph 302 shows the voltage through time at the SW node. Graph 304 shows the voltage through time at PGND. Graph 306 shows the voltage through time at AGND.

At 308 the voltage at the SW node is low and at steady state behavior. Likewise, at 310 and 312 PGND and AGND are both low and without noise. At 314 a switch occurs causes the voltage at the SW node to rise. Because of the switch, an impulse of noise at PGND appears at 316, and at 318 an impulse of noise occurs for AGND. At 320, a second switch occurs and causes the voltage at the SW node to decrease. This second switch causes noise at PGND, shown at 322, and noise at AGND, shown at 324.

The noise that appears at PGND, which is shown at 316 and 322, is larger than the noise that appears at AGND, which is shown at 318 and 324. Thus, it can be beneficial to connect a p-substrate to AGND, and to reference noise sensitive circuits to AGND. Furthermore, it can be beneficial to bias the guard ring 210 and the guard wall 202 with respect to AGND.

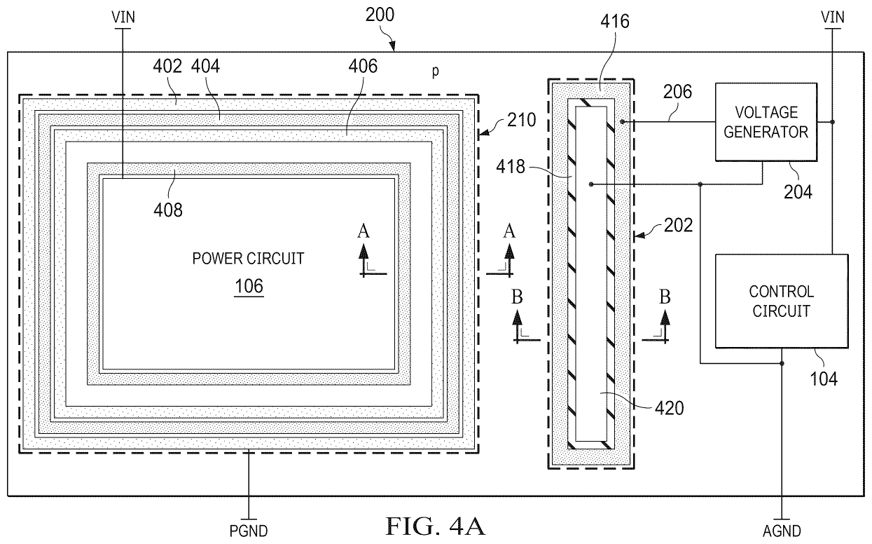

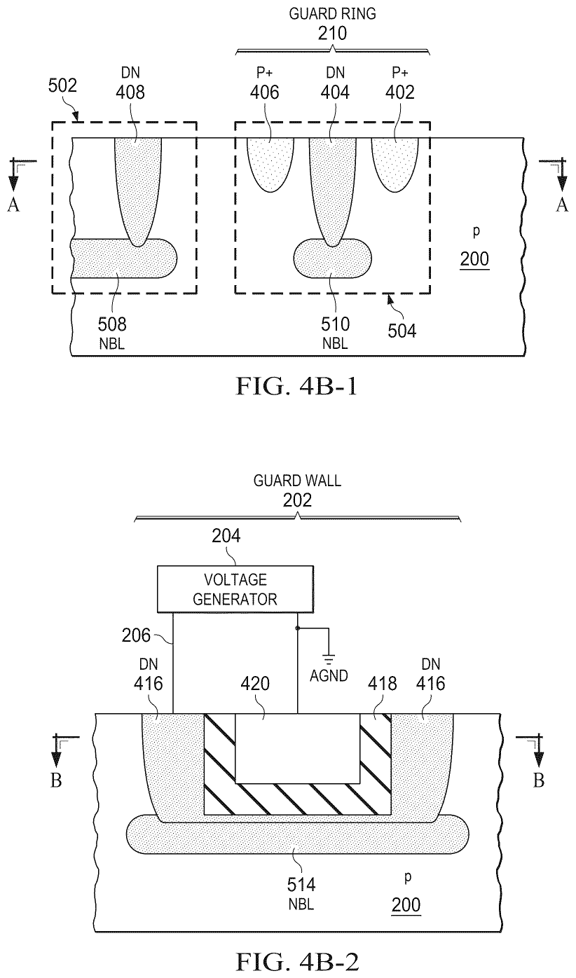

FIG. 4A shows a more detailed implementation of the top down view of FIG. 2. FIG. 4A shows doped regions 402, 404, 406, 408, 416, and 420. FIG. 4A also shows insulating region 418. FIG. 4A also shows the orientation for views AA and BB.

The doped regions of the guard ring 210, from outermost region to inner most region, are 402, 404, and 406. The regions of the guard wall 202, from outermost region to inner most region, are 416, 418, and 420. Doped regions 402 and 406 have a first doping polarity (e.g., are p-type). The doped regions 404 and 408 have a second doping polarity (e.g., are n-type). Doped region 416 has the first doping polarity. Doped region 420 has a high doping level, or degenerate doping level, and may be of the first doping polarity or the second doping polarity. Region 418 is an insulating region and is made of dielectric material, such as silicon dioxide or a high-k dielectric material. The doped regions of the guard ring 210 are spaced from each other. The regions of the guard wall 202 abut one another from the outermost region to the innermost region. Doped region 420 is surrounded by insulating region 418, and insulating region 418 is surrounded by doped region 416. View AA shows the regions of the guard ring 210, and view BB shows the regions of the guard wall 202. Doped region 420 may be polysilicon.

The doped regions of the guard ring 210 function to collect a large number of minority carriers generated within the substrate 200 (deepN in a p-type substrate) and/or to support recombination by providing distance and replenishing majority carriers (p-type substrate contacts) while reducing the risk for local debiasing of the substrate. The minority carriers may be the result of the power circuit 106 switching large currents and/or large voltages. Also, the doped regions of the guard ring 210 may not reduce the noise to a sufficiently low enough value. So, region 416, of the guard wall 202 functions to further collect minority carriers. The guard wall 202 is biased by the voltage generator 204 providing a voltage that in case of a p+ substrate is preferably positive with respect to substrate potential to doped region 416. Region 420 is biased to substrate potential which is AGND. Thus, the effect of the bias allows the guard wall 202 to function as a buried trench capacitor buffering the output of voltage generator 204 and to attract minority carriers.

FIG. 4B-1 shows a cross-sectional view of the guard ring 210 along line A-A of FIG. 4A, and FIG. 4B-2 shows a cross-sectional view of the guard wall 202 along line B-B of FIG. 4A. FIG. 4B-1 includes the regions from FIG. 4A and further shows a first isolation structure 502 used for isolating power circuit 106 having the isolation e.g. at VIN potential, and a guard ring structure 504. FIGS. 4B-1 and 4B-2 shows buried doped regions 508, 510, and 514.

The guard ring structure 504 is the guard ring 210. The first isolation structure 502 is used to isolate the power circuit from substrate and contains doped region 408 (which is illustrated as deep n-wells (DN)), and contains buried doped region 508 (which is illustrated for example as an n-type buried layer (NBL)). The doped region 408 contacts the buried doped region 508. The buried doped region 508 has the same doping polarity as the doped region 408. The first isolation structure 502 might be used to isolate e.g. transistor 110 or another noisy component of the power circuit 106 or the complete power circuit 106 from the substrate.

The guard ring structure 504 contains doped regions 402, 404, and 406. The guard ring structure 504 also contains buried doped region 510. Buried doped region 510 has a width that is less than the width of buried doped region 508. The doped region 404 contacts the buried doped region 510, and the doped region 404 has the same doping polarity as the buried doped region 510. Doped regions 402 and 406 have the same doping polarity, and have an opposite doping polarity from the doped region 404 and buried doped region 510. The doped regions 402, 404, and 406 within the guard ring structure 504 are all illustrated as being spaced apart from each other, but also could be in contact with one another. The doped region 404 extends deeper into the substrate 200 compared to doped region 402, and compared to doped region 406. Doped region 404 is laterally between doped regions 402 and 406.

The guard wall 202 includes the doped regions 416 and 420, and also includes insulating region 418 from FIG. 4A. The guard wall 202 further includes buried doped region 514. The doped region 416 contacts the buried doped region 514. Buried doped regions 508, 510, and 514 can be formed using a single mask and the same ion-implantation process as one another, such that 508, 510, and 514 can have the same doping profiles as one another and equal depths as one another. Similarly, doped regions 404, 408, and 416 can be formed using a single mask (different from the mask used to form buried doped regions) and the same ion-implantation process as one another, such that 404, 408, and 416 can have the same doping profiles as one another and equal depths as one another. The combination of the doped regions 416 and the buried doped region 514 form a U shape within the substrate 200. The insulating region 418 and doped region 420 are formed within this U shape. FIG. 4B-2 also shows the voltage generator 204 with a connection 206 to the doped region 416, and a connection from AGND (substrate potential) to the doped region 420. The doped region 416, buried doped region 514, insulating region 418, and doped region 420 form a (reverse biased) trench capacitor that functions to both buffer the output voltage of voltage generator 204 and to attract/collect minority carriers (electron collecting guard wall). The combination of functions is saving area.

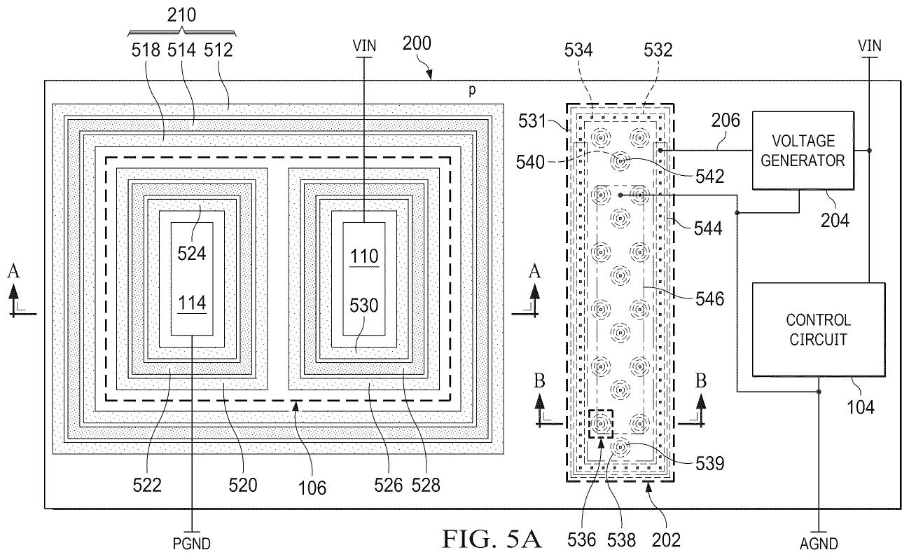

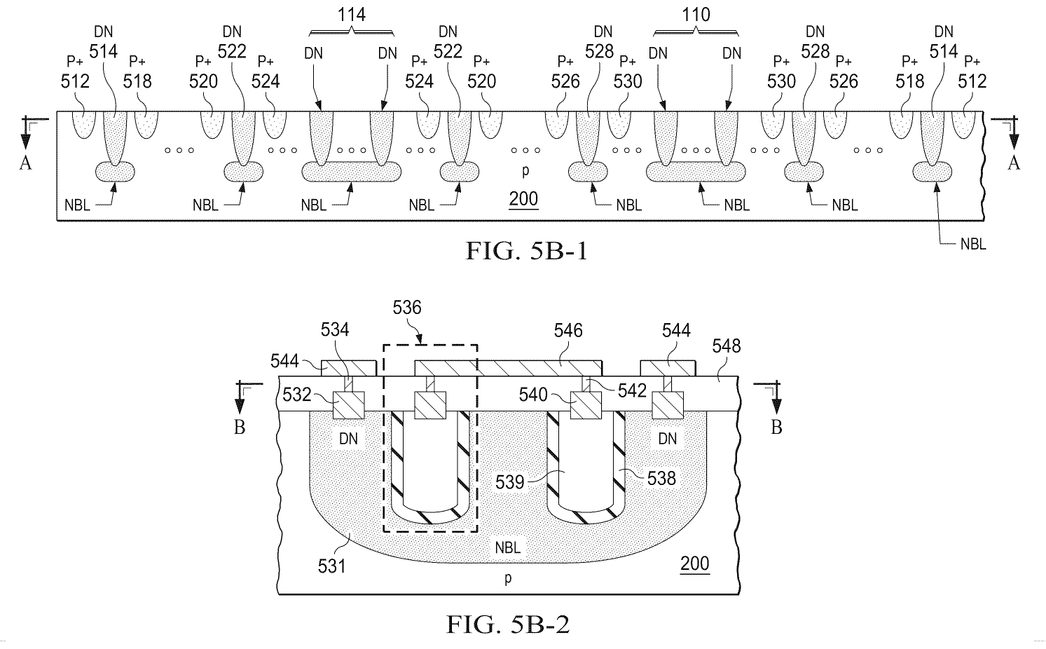

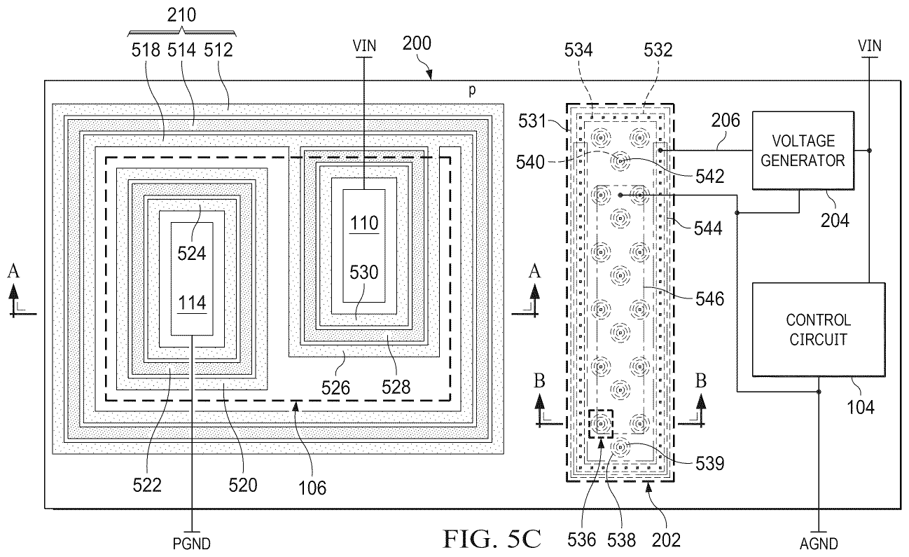

FIG. 5A shows another example implementation of a top-down view of FIG. 2. FIG. 5A shown the guard ring 210 comprising a first doped region 512, a second doped region 514, and a third doped region 518. The guard ring 210 laterally surrounds the power circuit 106. The second transistor 114 is shown being laterally surrounded by a fourth doped region 520, fifth doped region 522, and sixth doped region 524. The first transistor 110 is shown being laterally surrounded by a seventh doped region 526, an eighth doped region 528, and a ninth doped region 530. The VIN terminal connects to an isolation structure around the first transistor 110, and the PGND terminal connects to an isolation structure around the second transistor 114.

The doped regions surrounding the first transistor 110 and the second transistor 114 provide further isolation from the control circuit 104 and the voltage generator 204.

FIG. 5A also shows an example guard wall 202. The guard wall 202 shown in FIG. 5A has contact regions 532, contacts 534, trench capacitors 536, and doped well 531. Each of the trench capacitors 536 have an insulator region 538, a polysilicon region 539, a contact region 540, and a contact 542. FIG. 5A also shows a first conductive plate 544, and a second conductive plate 546. The guard wall 202 in FIG. 5A shows a pattern of alternating rows containing either a single trench capacitor or two trench capacitors. Other patterns may also be used, for example, another pattern may be four trench capacitors in a row, or the trench capacitors may be randomly distributed throughout the doped well 531. The second conductive plate 546 is only shown over a select number of trench capacitors 536, but the second conductive plate 546 may extend over more trench capacitors 536. For example, the second conductive plate 546 may extend over all of the trench capacitors 536. The first conductive plate 544 is only shown over a select number of contacts 534, but the first conductive plate 544 may extend over all of the contacts 534. For example, the first conductive plate 544 may wrap around outers sides of the guard wall 202, and be positioned over all of the contacts 534.

The contact regions 532 may be made of a conductive material. For example, the contact regions 532 may be made of titanium, tungsten, copper, or any other suitable conductive material. The insulator region 538 may be made of an insulator material. For example, the insulator region 538 may be made of silicon dioxide, a high-k material, or any other suitable insulating material. The polysilicon region 539 may be made of a conductive material. For example, the polysilicon region 539 may be silicon with heavy doping, or any other suitable conductive material. The contact 542 may be made of a conductive material. For example, the contact 542 may be made of copper, aluminum, or any other suitable conductive material. The first conductive plate 544 and the second conductive plate 546 may also be made of a conductive material, for example, copper, aluminum, or any other suitable conductive material.

The trench capacitors 536 are shown with a circular shape, but may instead have different shapes. For example, the trench capacitors may have a rectangular shape, a hexagonal shape, or have sides with an irregular pattern. Additionally, the number of trench capacitors may vary. For example, there may be between 1 and 10 trench capacitors, or between 10 and 10,000 trench capacitors. The doped well 531 is connected to the connection 206 of the voltage generator 204 through contacts 534. The trench capacitors 536 is connected to AGND by contact 542. Thus, the trench capacitors 536 store a charge. This allows the trench capacitors to attract minority carriers within the substrate to further reduce noise.

The insulator region 538, the polysilicon region 539, the contact region 540, and the contact 542 may have different shapes, for example they may be circular, rectangular, hexagonal, or any other suitable shape. The insulator region 538, the polysilicon region 539, the contact region 540, and the contact 542 may also have different shapes from each other, or have the same shape as each other.

FIG. 5B-1 shows cross-section A-A of FIG. 5A. Along cross section A-A from left to right is the guard ring 210 containing the first doped region 512, second doped region 514, and third doped region 518. Further the cross-section A-A shows, the fourth doped region 520, fifth doped region 522, sixth doped region 524, the second transistor 114 laterally surrounded by a DN-NBL-DN isolation structure, the sixth doped region 524, the fifth doped region 522, the fourth doped region 520. Three dots shows that other circuits may be present. The cross-section A-A also shows from left to right the seventh doped region 526, the eight doped region 528, the ninth doped region 530, the first transistor 110 laterally surrounded by a DN-NBL-DN isolation structure, the ninth doped region 530, the eight doped region 528, the seventh doped region 526.

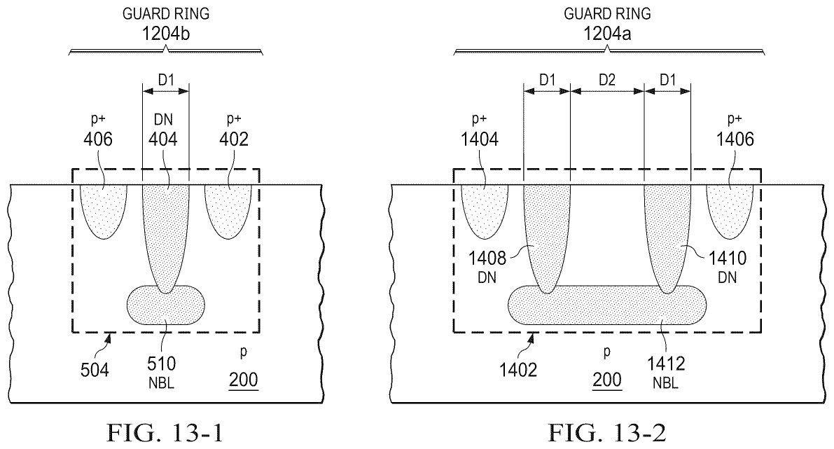

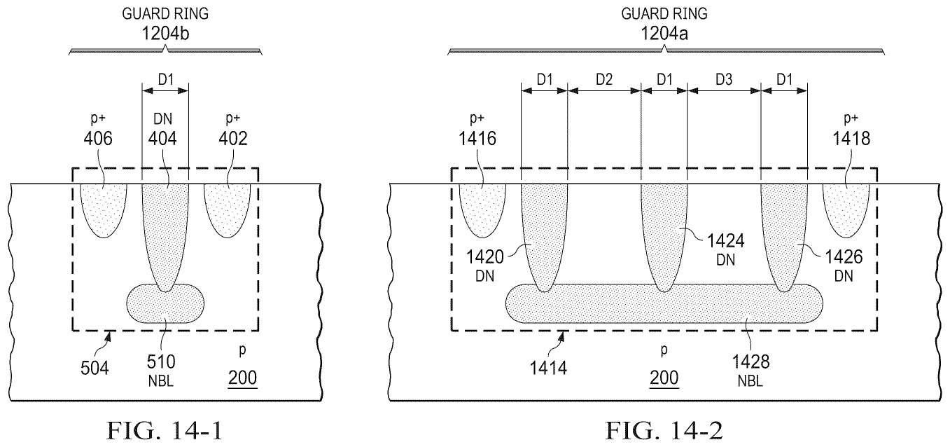

It is noted that combinations of the doped regions, for example doped regions 512, 514, and 518, or doped regions 520, 522, and 524, or doped region 526, 528, and 530, may be replaced with a structure that is thicker. For example, they may be replaced with the extended isolation structure 1402 shown in FIG. 13-2, or with the elongated isolation structure 1414 shown in FIG. 14-2.

FIG. 5B-2 shows cross-section B-B from FIG. 5A. Along cross-section B-B is contact region 532, contact 534, first conductive plate 544, trench capacitor 536, doped well 531, second conductive plate 546, contact region 540, contact 542, polysilicon region 539, insulator region 538, and epitaxial layer 548.

The contact region 540 is larger than the contact 542 to allow a region for the contact 542 to be positioned. The polysilicon region 539 is larger than the contact region 540. The insulator region 538 surrounds three sides of the polysilicon region 539. The doped well 531 surrounds three sides of the insulator region 538.

The polysilicon region 539 is highly doped to be conductive. The doped well 531 is highly doped to be conductive. The insulator region 538 isolates the polysilicon region 539 from the doped well 531. Thus, the polysilicon region 539, insulator region 538, and doped well 531 functions as a capacitor. The epitaxial layer 548 provides isolation over a top surface of the substrate 200.

FIG. 5C shows another example top view similar to the top view shown in FIG. 5A. In FIG. 5C the first transistor 110 is positioned upwards to share a doped region with the guard ring 210. More specifically, the seventh doped region 526 overlaps with the third doped region 518. Although not shown, it is understood that any other doped regions may overlap, for example the eighth doped region 528 may overlap with the second doped region 514. This can be beneficial for saving wafer area while still achieving diode-diode isolation in both directions.

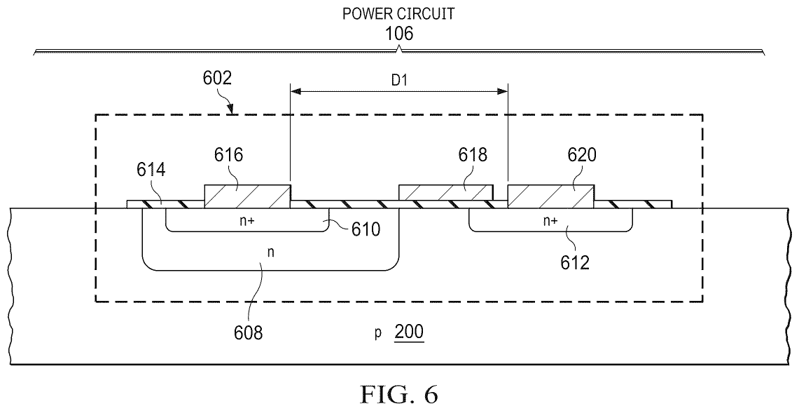

FIG. 6 shows a cross-section of the power circuit 106 having a first type of transistor. FIG. 6 shows a lateral diffusion metal oxide semiconductor field effect transistor (LD-MOSFET) 602. The LD-MOSFET 602 contains a drift region 608, a first doped region 610, a second doped region 612, a first terminal 616, a second terminal 620, a control terminal 618, and an insulating region 614.

The drift region 608 is doped n-type and surrounds the first doped region 610. The first doped region 610 and the second doped region 612 are doped n+ and are spaced from each other. The first terminal 616 is over the first doped region 610, and the first terminal 616 is directly contacting the first doped region 610. The second terminal 620 is over the second doped region 612, and the second terminal 620 is directly contacting the second doped region 612. The control terminal 618 is spaced from the first terminal 616 and the second terminal 620, and the control terminal 618 is placed between the first terminal 616 and the second terminal 620. The control terminal is contacting the insulating region 614.

The first doped region 610 and the second doped region 612 have a conductance between each other modulated by the control terminal 618 that is placed above where a channel is to be formed. The drift region 608 provides further isolation between the first doped region 610 and second doped region 612, so that the LD-MOSFET 602 can switch higher voltages. This is because the breakdown voltage is increased from the spacing, D1, between the first terminal 616 and the second terminal 620.

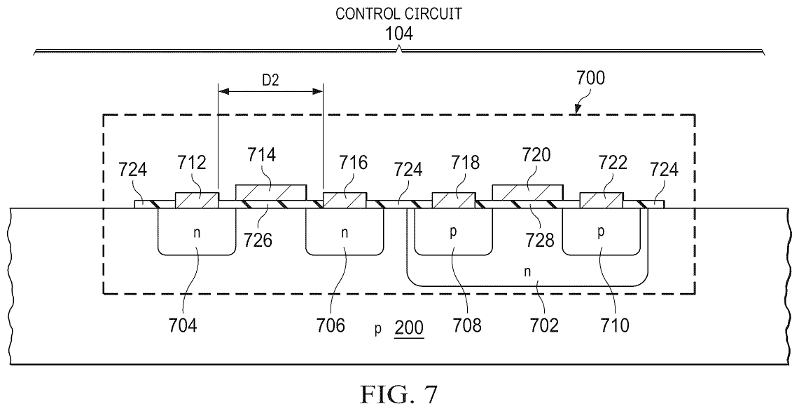

FIG. 7 shows a cross-section of the control circuit 104 having a second type of transistor. FIG. 7 shows an example of a complementary metal oxide semiconductor field effect transistor (MOSFET) 700 implementation used in the control circuit 104. The complementary MOSFET has a doped well 702, a first doped region 704, a second doped region 706, a third doped region 708, a fourth doped region 710, a first terminal 712, a first control terminal 714, a second terminal 716, a third terminal 718, a second control terminal 720, a fourth terminal 722, an insulating region 724, a first dielectric region 726, and a second dielectric region 728.

The first doped region 704 and the second doped region 706 have the same doping polarity in region within the substrate 200. The first doped region 704 and the second doped region 706 are spaced from each other. The first dielectric region 726 is above the substrate 200 and lies in the space above where the first doped region 704 and the second doped region 706 are spaced from each other. The first control terminal 714 is above the first dielectric region 726. The first terminal 712 is above the first doped region 704. The second terminal 716 is above the second doped region 706. The first control terminal 714 is between the first terminal 712 and the second terminal 716.

The doped well 702 is within the substrate 200 and surrounds the third doped region 708 and the fourth doped region 710. The doped well 702 has an opposite polarity to the doping polarity of the third doped region 708 and the fourth doped region 710. The third doped region 708 and the fourth doped region 710 are within the substrate 200 and are spaced from each other. The second dielectric region 728 is on the top of the substrate 200 and is above the space between the third doped region 708 and the fourth doped region 710. The third terminal 718 is above the third doped region 708, and the fourth terminal 722 is above the fourth doped region 710. The second control terminal is between the third terminal 718 and the fourth terminal 722. The insulating region 724 is on top of the substrate 200 and is contacting an outer side of the first terminal 712, the sides of the second terminal 716 and the third terminal 718, and the outer side of the fourth terminal 722.

The first doped region 704, second doped region 706, and first control terminal function as a n-type field effect transistor. The third doped region 708, the fourth doped region 710, and the second control terminal 720 function a p-type field effect transistor. Because the n-type transistor and the p-type transistor are along a top side, they are planar MOSFETs. The n-type field effect transistor and the p-type field effect transistor may have a distance, D2, between the first terminal 712 and the second terminal 716 that is smaller than the distance D1. Thus, D1 may be wider than D2.

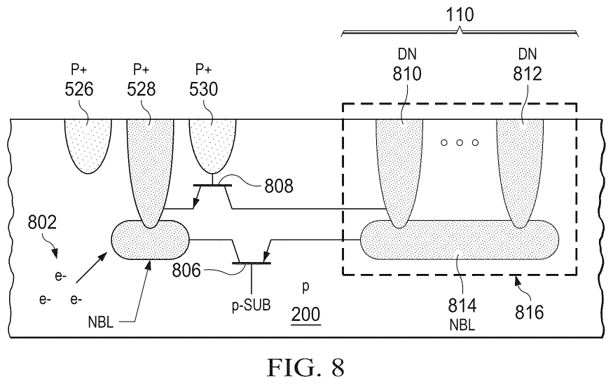

FIG. 8 shows a zoomed in cross-section of FIG. 5B-1 with parasitic devices shown. FIG. 8 shows an isolation structure 816 that laterally surrounds the first transistor 110 and contains doped regions 810, 812, and NBL layer 814. The parasitic devices include, a first BJT transistor 806, and a second BJT transistor 808. Also, FIG. 8 shows minority carriers 802.

The first BJT transistor 806 has a first terminal connected to the doped region 528, a second terminal connected to a NBL layer 814, and a control terminal connected to the substrate 200. The second BJT transistor 808 has a first terminal connected to the doped region 528, and has a second terminal connected to the doped region 810, and has a control terminal connected to the doped region 530. It is noted that many more parasitic devices may exist in this structure, not all of them are shown.

The first BJT transistor 806 show the doped region 528 functioning as a collector, which means the doped region 528 is collecting the minority carriers, such as the electrons shown at 802. This function of the first BJT transistor 806 reduce the substrate noise. Also, the second BJT transistor 808 shows the doped region 528 functioning as an emitter. This behavior as an emitter is to be limited so that extra minority carriers are not further added to the substrate 200. In order to limit this behavior, the doped regions 526 and 530 are on both sides of the doped region 528. The doped regions 526 and 530, by having a high doping concentration in an opposite polarity, function as substrate contacts and are shorting locally the base of the second BJT transistor 808 to its emitter since 526, 528 and 530 are locally shorted together and connected to substrate potential AGND. Thus, the doped region 528 is impaired from becoming an active emitter junction.

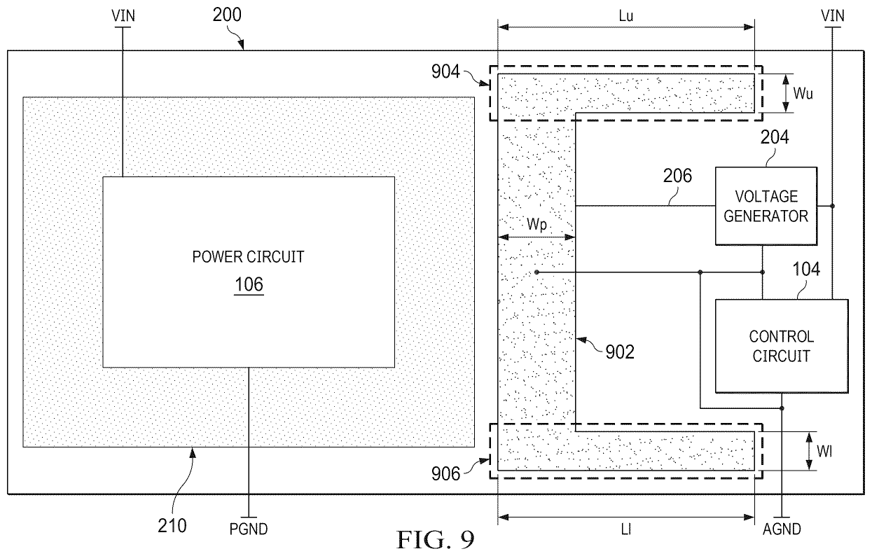

FIG. 9 shows an alternative geometric layout of the guard wall 902 from a top view compared to FIG. 2. In FIG. 9, the guard wall 902 has an upper portion 904 and a lower portion 906. The upper portion 904 of the guard wall 902 extends partially towards to voltage generator 204 and towards to control circuit 104 by length. The lower portion 906 of the guard wall 902 extends partially towards the voltage generator 204 and the control circuit 104 by lengths Lu, and Ll. The upper portion 904 and the lower portion 906 may extend at the same length (Lu=Ll) towards the voltage generator 204 and the control circuit 104. Thus, the guard wall 902 may have a C shape when viewed from this top-down view. Alternatively, the upper portion 904 and the lower portion 906 may extend at different lengths (Lu<Ll or Lu>Ll) from one another from left to right in FIG. 9, which is not shown.

The guard wall 902 containing the upper portion 904 and the lower portion 906 functions to minimize the minority carriers in the substrate. This is because any minority carrier that is generated by the power circuit 106 travels a distance around the upper portion 904, or around the lower portion 906. Because the minority carrier has a further distance to travel, the probability that the minority carrier is collected by upper portion 904 or lower portion 906 or undergoes recombination is increased. Thus, by causing minority carriers to travel a further distance, the upper portion 904 and the lower portion 906 of the guard wall 902 further decrease noise. FIG. 9's guard wall 902, which includes multiple linear segments rather than a single linear segment as illustrated in FIG. 2, has an increased area/footprint compared to that of FIG. 2. Thus, FIG. 9 may provide slightly better current leakage protection relative to FIG. 2, but is also more expensive in terms of footprint/area. In the example of FIG. 9, the upper and lower portions can have widths (e.g., Wu and Wl) that are slightly less than the width of the primary segment Wp. This helps to reduce the overall area of the guard wall 902 somewhat, while still retaining some benefit of the upper and lower portions 904, 906.

FIG. 10 shows an alternative geometric layout of the guard wall 1002 from a top view compared to FIG. 2 and compared to FIG. 9. In FIG. 10, the guard wall 1002 surrounds the voltage generator 204 and the control circuit 104. This has the benefit of reducing noise due to minority carriers. However, the guard wall 1002 also uses significantly more substrate area.

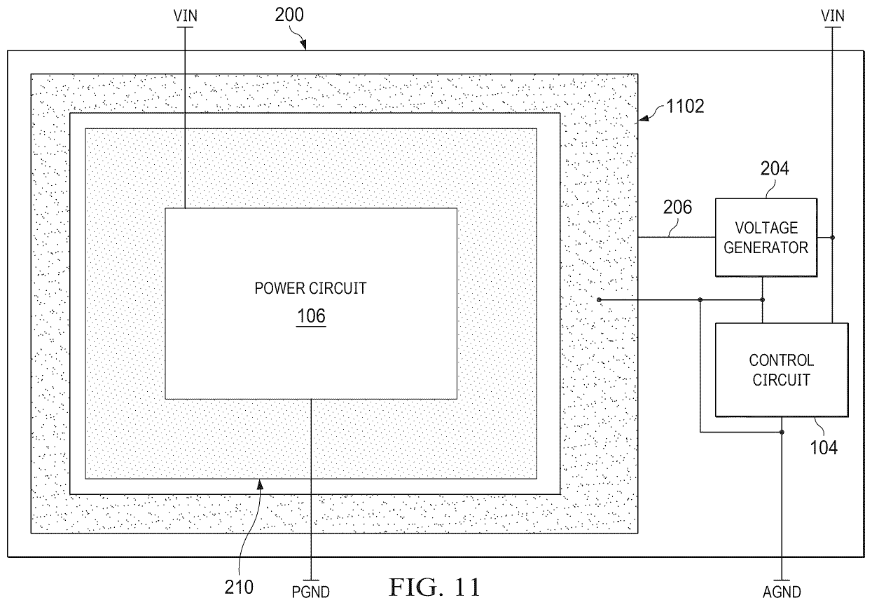

FIG. 11 shows an alternative geometric layout of the guard wall 1102 from a top view compared to FIG. 2, FIG. 9, and FIG. 10. In FIG. 11, the guard wall 1102, surrounds the guard ring 210. This may have an advantage of further reducing the noise. While the guard wall 1102 surrounding the guard ring 210 may significantly reduce noise, the power circuit 106 may take up a larger amount of area compared to the control circuit 104 and compared to the voltage generator 204. Thus, the guard wall 1102 may require a large amount of area.

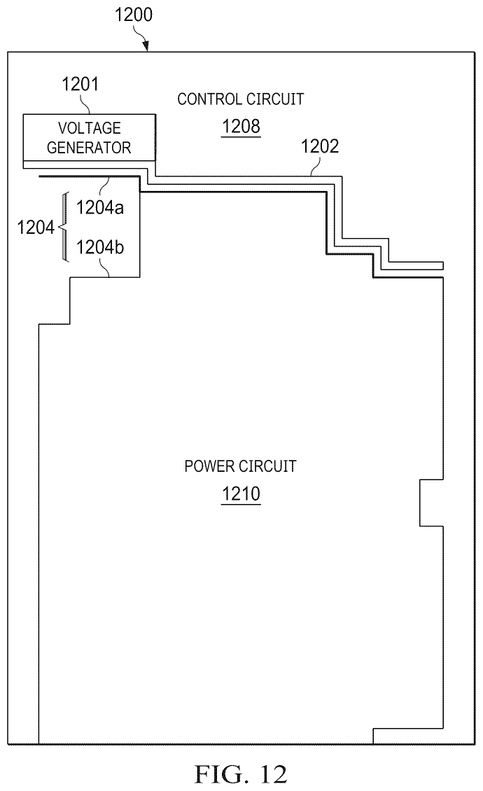

FIG. 12 shows a top view of an implementation of the device. This view shows a substrate 1200, a voltage generator 1201, a guard wall 1202, a guard ring 1204 containing a thick region 1204a and a thin region 1204b. This view also shows control circuit 1208 and power circuit 1210.

The power circuit 1210 and the control circuit 1208 both have multiple stair-stepped profiles around their outer perimeters. So, the power circuit 1210 and the control circuit 1208 have varying widths and lengths along a horizontal and vertical axis of the substrate 1200. Guard ring 1204 containing both the thick region 1204a and the thin region 1204b surrounds the power circuit 1210. The thick region 1204a of the guard ring 1204 is between the control circuit 1208 and the power circuit 1210. Also, the guard wall 1202 is between the control circuit 1208 and the power circuit 1210. The voltage generator 1201 is positioned next to the control circuit 1208, and is outside of the guard ring 1204. The voltage generator 1201 is directly contacting the guard wall 1202. The thick region 1204a of the guard ring 1204 can extend past the area enclosed by the guard ring 1204.

The power circuit 1210 and control circuit 1208 may perform the same function as shown in FIG. 1. In the example shown in FIG. 12, the power circuit 1210 takes up a larger area of the substrate 1200. The thick region 1204a of the guard ring 1204 is more effective at reducing noise compared to the thin region 1204b of the guard ring 1204. However, the thick region 1204a of the guard ring 1204 uses more area than the thin region 1204b of the guard ring 1204. Thus, it is beneficial to set only a region of the guard ring 1204 to be thick. More specifically, setting the region of the guard ring 1204 that is between the power circuit 1210 and the control circuit 1208 to be thick may lead to the greatest noise reduction.

FIG. 13-1 provides a cross-section view of the thin region 1204b of the guard ring 1204. FIG. 13-2 provides a cross-section of the thick region 1204a of the guard ring 1204. The thin region 1204b of the guard ring is similar to that shown in FIG. 4B-1. The thick region 1204a of the guard ring 1204 has an extended isolation structure 1402. The extended isolation structure 1402 has deep doped regions 1408 and 1410 touching an extended n buried layer NBL 1412, and also has doped layers 1404 and 1406 on both sides of the deep doped regions 1408 and 1410.

The deep doped region 408 of the guard ring structure 504 has a width, D1, of its doping due to processing technology. Similarly, the deep doped regions 1408 and 1410 of the extended isolation structure 1402 also have the same width, D1. Further, the distance between deep doped regions 1408 and 1410 is equal to D2, and D2 may be less than, equal to, or larger than D1. Thus, the entire width of the deep doped regions 1408 and 1410 and NBL 1412 may be three times larger than the width of the deep doped region 408 and NBL 510. The distances D1 and D2 may be between 2 um and 6 um, or between 1 um and 8 um.

FIG. 14-1 provides another example cross-section view of the thin region 1204b of the guard ring 1204. FIG. 14-2 provides another example cross-section view of the thick region 1204a of the guard ring 1204. In this example, the thin region 1204b is the same as shown in FIG. 13-1. The thick region 1204a has an elongated isolation structure 1414. The elongated isolation structure has three deep doped regions 1420, 1424, and 1426, and a n buried layer NBL 1428. The elongated isolation structure further has doped regions 1416 and 1418 on both sides of the three deep doped regions.

Each of the deep doped regions has a width, D1, that is equal to the width of the deep doped region of the guard ring structure 504. Additionally, the distance between the deep doped regions 1420 and 1424 is D2, and the distance between deep doped regions 1424 and 1426 is equal to D3, with D2 and D3 being less than, equal, or larger than D1. Thus, the elongated isolation structure 1414 may have a width that is five times larger than the width of the guard ring structure 504. While examples are shown of the thick region having two or three deep doped regions, it is understood that more deep doped regions may be present. For example, the number of deep doped regions may be between 1 and 5, or between 10 and 1000.

This additional width of the thick region 1204a may reduce the noise at the cost of extra wafer area.

The methods are illustrated and described above as a series of acts or events, but the illustrated ordering of such acts or events is not limiting. For example, some acts or events may occur in different orders and/or concurrently with other acts or events apart from those illustrated and/or described herein. Also, some illustrated acts or events are optional to implement one or more aspects or embodiments of this description. Further, one or more of the acts or events depicted herein may be performed in one or more separate acts and/or phases. In some embodiments, the methods described above may be implemented in a computer readable medium using instructions stored in a memory.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are illustrated and/or described herein, other transistors (or equivalent switching devices) may be used instead with little or no change to the remaining circuitry. For example, a metal-oxide-silicon FET (“MOSFET”) (such as an n-channel MOSFET, nMOSFET, or a p-channel MOSFET, pMOSFET), a bipolar junction transistor (BJT—e.g. NPN or PNP), insulated gate bipolar transistors (IGBTs), and/or junction field effect transistor (JFET) may be used in place of or in conjunction with the devices described herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero. Modifications are possible in the described examples, and other implementations are possible, within the scope of the claims.

What is claimed is:

1. A device comprising:
a power circuit disposed within a substrate and including a transistor of a first type, the power circuit having a ground terminal coupled to a first ground supply terminal;
a control circuit disposed within the substrate and including a transistor of a second type different from the first type, the control circuit being coupled to the power circuit, and the control circuit having a ground terminal coupled to a second ground supply terminal different from the first ground supply terminal;
a guard ring including a plurality of doped regions within the substrate, the guard ring laterally surrounding the power circuit;
a guard wall disposed within the substrate between the guard ring and the control circuit, the guard wall including a first doped region laterally surrounding an insulating region, and a polysilicon region laterally surrounded by the insulating region, the polysilicon region of the guard wall being connected to the second ground supply terminal; and
a voltage generator within the substrate, the voltage generator having a first terminal coupled to the first doped region of the guard wall.

2. The device of claim 1, wherein the power circuit includes a lateral diffusion metal oxide semiconductor field effect transistor (LD-MOSFET), wherein the control circuit includes a planar MOSFET, and wherein the LD-MOSFET has a width between a source terminal and a drain terminal that is wider than a width between a source terminal and a drain terminal of the planar MOSFET.

3. The device of claim 1, wherein the guard ring comprises a first doped ring, a second doped ring, and a third doped ring, wherein the first doped ring and the third doped ring have a first doping polarity, and wherein the second doped ring has a second doping polarity opposite the first doping polarity, and wherein the second doped ring extends further into the substrate compared to both the first doped ring and the third doped ring.

4. The device of claim 1, wherein the guard ring comprises an isolation structure including a first doped region, a second doped region, a deep doped region, and a buried doped region, the first doped region of the isolation structure and the second doped region of the isolation structure both have a first doping polarity, the deep doped region of the isolation structure and the buried doped region of the isolation structure having a second doping polarity.

5. The device of claim 4, wherein the deep doped region of the isolation structure is between the first doped region and the second doped region of the isolation structure, and wherein the deep doped region of the isolation structure extends further into the substrate than both the first doped region and the second doped region of the isolation structure.

6. The device of claim 5, wherein the guard wall further comprises a buried doped region, and wherein the first doped region of the guard wall is contacting the buried doped region of the guard wall, and wherein the first doped region of the guard wall and the buried doped region of the guard wall both have the first doping polarity, and wherein the first doped region of the guard wall and the buried doped region of the guard wall both extend around the insulating region.

7. The device of claim 1, wherein the guard wall laterally surrounds the control circuit.

8. The device of claim 1, wherein the guard wall laterally surrounds the guard ring.

9. The device of claim 1, wherein the guard ring includes a first region and a second region, wherein the first region has a thickness that is larger than a thickness of the second region.

10. An integrated circuit comprising:
a first transistor having a first terminal, a second terminal, and a control terminal;
a second transistor having a first terminal, a second terminal, and a control terminal, the first terminal of the second transistor is connected to the second terminal of the first transistor;
a circuit having an input terminal, a first output terminal, and a second output terminal, the input terminal coupled to the second terminal of the first transistor, the first output terminal coupled to the control terminal of the first transistor, and the second output terminal coupled to the control terminal of the second transistor, wherein first transistor, the second transistor, and the circuit are all implemented on a substrate; and
a guard ring including a first doped region, a second doped region, a third doped region, and a buried doped region laterally surrounding the first transistor and the second transistor, the second doped region extending further into the substrate than the first doped region or the third doped region, and the second doped region contacting the buried doped region.

11. The circuit of claim 10, further comprising:
a guard wall including a first doped region, an insulating region, and a polysilicon region disposed within the substrate, wherein the guard wall is positioned between the guard ring and the circuit.

12. The circuit of claim 11, further comprising:
a voltage generator having a terminal coupled to the first doped region of the guard wall, and wherein the first doped region of the guard wall laterally surrounds the insulating region of the guard wall.

13. The circuit of claim 10, wherein the first doped region and the third doped region have a first doping polarity, and wherein the second doped region and the buried doped region have a second doping polarity, and wherein the first doping polarity is opposite the second doping polarity.

14. The circuit of claim 13, wherein the second doped region is laterally between the first doped region and the third doped region.

15. The circuit of claim 10, wherein the first terminal of the first transistor is coupled to a first voltage supply terminal, and wherein the circuit has a voltage input terminal coupled to the first voltage supply terminal.

16. The circuit of claim 10, wherein the circuit has a ground input terminal coupled to a first ground, and wherein the second terminal of the second transistor is coupled to a second ground, the first ground being different from the second ground.

17. An integrated circuit comprising:
a first circuit disposed within a substrate;
a second circuit disposed within the substrate and spaced apart from the first circuit;
a first doped region laterally surrounding the first circuit when viewed from a top-down view, the first doped region having a first doping polarity;
a second doped region laterally surrounding the first doped region when viewed from the top-down view, the second doped region having a second doping polarity, the second doping polarity being opposite the first doping polarity;
a third doped region laterally surrounding the second doped region when viewed from the top-down view, the third doped region having the first doping polarity, wherein the second doped region extends further into the substrate than both the first doped region and the third doped region when viewed in a cross-sectional view; and
a polysilicon region extending along a linear segment that separates the first circuit and the second circuit when viewed from the top-down view, the polysilicon region not entirely laterally surrounding the first circuit when viewed from the top-down view and not entirely laterally surrounding the second circuit when viewed from the top-down view.

18. The integrated circuit of claim 17, wherein the first, second, and third doped regions are concentric with one another, and further comprising a buried doped region, wherein the buried doped region has the second doping polarity, and wherein the second doped region contacts the buried doped region.

19. The integrated circuit of claim 18, wherein the buried doped region is deeper in the substrate than the first doped region and the second doped region.

20. The integrated circuit of claim 19, further comprising:
an insulating region extending along a first side, a bottom, and a second side of the polysilicon region;
a fourth doped region having the second doping polarity and extending along a first side, a bottom, and a second side of the insulating region; and
a voltage generator with a terminal coupled to the fourth doped region.
